(19) United States
(12) Patent Application Publication
(10) Pub. No.: US 2018/0347785 A1
(43) Pub. Date: Dec. 6, 2018

(54) LIGHT-EMITTING DEVICE

(71) Applicant: SHARP KABUSHIKI KAISHA, Sakai City, Osaka (JP)

(72) Inventors: YOSHINOBU KAWAGUCHI, Sakai City (JP); KAZUNORI ANNEN, Sakai City (JP); KOJI TAKAHASHI, Sakai City (JP); YOSHIYUKI TAKAHIRA, Kizugawa City, Kyoto (JP); YOSUKE MAEMURA, Sakai City (JP); TOMOHIRO SAKAUE, Sakai City (JP)

(21) Appl. No.: 15/756,222

(22) PCT Filed: May 17, 2016
(86) PCT No.: PCT/JP2016/064608

§ 371 Date: Feb. 28, 2018

(30) Foreign Application Priority Data
Sep. 3, 2015 (JP) 2015-174160

(51) Int. Cl. F21V 7/22; F21S 2/00; F21V 9/30; G02B 5/26; G02B 5/28; H01S 5/022; F21K 9/90; F21S 41/16; F21S 41/24

(52) U.S. Cl. CPC F21V 7/22; F21S 2/00; F21V 9/30; G02B 5/26; F21Y 2115/10; H01S 5/022; F21K 9/90; F21S 41/16; F21S 41/24; G02B 5/28

(57) ABSTRACT

When a phosphor layer formed of a small-gap phosphor plate is used, color irregularity of illumination light emitted from a light-emitting device is reduced. The light-emitting device (100) which emits laser light (L1) as part of illumination light includes a semiconductor laser (10a to 10c) which emits the laser light (L1), which is visible light, a phosphor layer (1a) formed of a small-gap phosphor plate which emits a fluorescence (L2) upon reception of the laser light (L1) emitted from the semiconductor laser (10a to 10c), and an excitation light distribution control unit (1b) which controls light distribution of the laser light (L1) and guides the laser light (L1) to inside of the phosphor layer (1a). The small-gap phosphor plate is a phosphor plate in which a gap that is present inside has a width equal to or longer than 0 nm and equal to or shorter than one tenths of a wavelength of the laser light (L1).

### TECHNICAL FIELD

The present invention relates to a light-emitting device.

### BACKGROUND ART

In recent years, light-emitting devices with semiconductor light-emitting elements such as light emitting diodes (LEDs) and phosphors (wavelength conversion members) combined together have been developed. These light-emitting devices have advantages of a small size and lower power consumption than that of incandescent lamps, and thus have been put into practical use as light sources of various display devices and illumination devices.

And, for the purpose of improvement in performance or convenience of the light-emitting devices, various light-emitting devices have been suggested. For example, PTL 1 discloses a light-emitting device for the purpose of improvement against luminance saturation or thermal quenching which locally occurs when high-density laser lights are gathered and radiated in a spot manner.

Also, PTL 2 discloses a light source device for the purpose of ensuring safety for human eyes and improving color mixture of luminescent colors. Also, PTL 3 discloses a fluorescence light source device for the purpose of achieving high luminous efficiency and acquiring highly-uniform light without an occurrence of color irregularity.

### CITATION LIST

### Patent Literature

PTL 1: Japanese Unexamined Patent Application Publication No. 2014-67961 (published on Apr. 17, 2014)

PTL 2: Japanese Unexamined Patent Application Publication No. 2012-182376 (published on Sep. 20, 2012)

PTL 3: Japanese Unexamined Patent Application Publication No. 2015-69885 (published on Apr. 13, 2015)

### SUMMARY OF INVENTION

### Technical Problem

Meanwhile, the use of a phosphor layer formed of a small-gap phosphor plate as a wavelength conversion member has been studied recently. Note that the definition of the small-gap phosphor plate will be described further below. As will be described further below, the phosphor layer formed of the small-gap phosphor plate has very low scattering properties of light (excitation light and fluorescence).

However, when the phosphor layer formed of the small-gap phosphor plate is used, a technical idea of reducing color irregularity of illumination light emitted from the light-emitting device is not considered in PTL 1 and PTL 3 described above. Also in PTL 2, while the technical idea is considered, the consideration cannot be said as sufficient. Therefore, the inventions according to PTL 1 to PTL 3 have a problem in that color irregularity of illumination light emitted from the light-emitting device cannot be reduced sufficiently when the phosphor layer formed of the small-gap phosphor plate is used.

The present invention was made to solve the above problems, and has a purpose of providing a light-emitting device capable of reducing color irregularity of illumination light emitted from the light-emitting device when the phosphor layer formed of the small-gap phosphor plate is used.

### Solution to Problem

To solve the above problems, a light-emitting device according to one mode of the present invention is a light-emitting device which emits excitation light as part of illumination light. The light-emitting device includes an excitation light source which emits the excitation light, which is visible light, a phosphor layer formed of a small-gap phosphor plate which emits a fluorescence upon reception of the excitation light emitted from the excitation light source, and an excitation light distribution control unit which controls light distribution of the excitation light and guides the excitation light to the inside of the phosphor layer, and the small-gap phosphor plate is a phosphor plate in which a gap that is present inside has a width equal to or longer than 0 nm and equal to or shorter than one tenths of a wavelength of the excitation light.

### Advantageous Effects of Invention

According to a light-emitting device of one mode of the present invention, an effect can be achieved in which color irregularity of illumination light emitted from the light-emitting device can be reduced when the phosphor layer formed of the small-gap phosphor plate is used.

### BRIEF DESCRIPTION OF DRAWINGS

FIG. 1(a) is a diagram depicting the structure of a light-emitting device according to a first embodiment of the present invention, and FIG. 1(b) is a diagram schematically depicting the structure of a light-emitting unit included in the light-emitting device.

FIG. 2(a) and FIG. 2(b) are diagrams each depicting a specific example of the structure of an excitation light distribution control unit in the light-emitting device according to the first embodiment of the present invention.

FIG. 3 is a schematic diagram for describing a gap width in a phosphor plate (small-gap phosphor plate) according to the first embodiment of the present invention.

FIG. 4(a) and FIG. 4(b) are diagrams each depicting a comparative example of the light-emitting unit according to the first embodiment of the present invention.

FIG. 5 is a diagram schematically depicting the structure of the periphery of a light-emitting unit included in a light-emitting device according to a second embodiment of the present invention.

FIG. 6 is a diagram depicting one example of an optical property of a dichroic mirror in the second embodiment of the present invention.

FIG. 7 is a diagram schematically depicting the structure of the periphery of a light-emitting unit included in a light-emitting device according to a third embodiment of the present invention.

FIG. 8 is a diagram schematically depicting the structure of the periphery of a light-emitting unit included in a light-emitting device according to a fourth embodiment of the present invention.

FIG. 9 is a diagram schematically depicting the structure of the periphery of a light-emitting unit included in a light-emitting device according to a fifth embodiment of the present invention.

### DESCRIPTION OF EMBODIMENTS

### First Embodiment

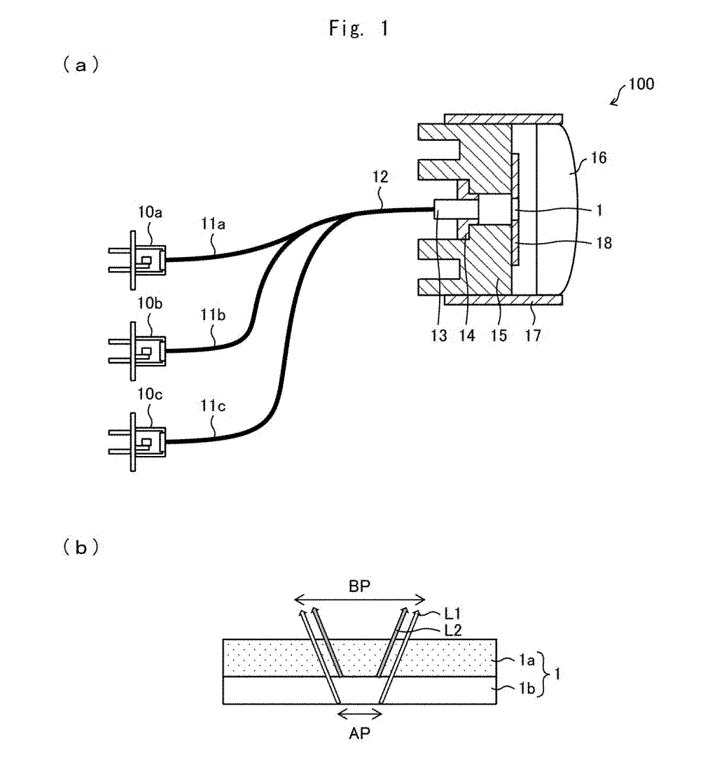

A first embodiment of the present invention is described based on FIG. 1 to FIG. 4 as follows.

### (Structure of Light-Emitting Device 100)

(a) of FIG. 1 is a diagram depicting the structure of a light-emitting device 100 of the present embodiment. Also, (b) of FIG. 1 is a diagram schematically depicting the structure of a light-emitting unit 1 included in the light-emitting device 100. The light-emitting device 100 includes the light-emitting unit 1, semiconductor lasers 10a to 10c (excitation light sources), optical fibers 11a to 11c, a bundle fiber 12, a ferrule 13, a ferrule fixing unit 14, a fixing unit 15, a lens 16 (optical transmission system), a lens fixing unit 17, and a heat dissipating unit 18.

The light-emitting device 100 is configured so that laser lights (excitation lights) in blue emitted from the semiconductor lasers 10a to 10c and a fluorescence in yellow emitted from a phosphor included in the light-emitting unit 1 are transmitted by the lens 16 to a specific direction. Note that, as will be described further below, the phosphor is, for example, an yttrium aluminum garnet (YAG) monocrystalline phosphor.

Light with these laser lights in blue and the fluorescence in yellow mixed together is emitted as illumination light in white (more strictly, pseudo white) to the outside of the light-emitting device 100. The light-emitting device 100 may be used as a spotlight, a headlight for vehicles, or the like.

First, with reference to (a) of FIG. 1, each member except the light-emitting unit 1 is described. The semiconductor lasers 10a to 10c are three excitation light sources which emit excitation light to excite a phosphor included in the light-emitting unit 1. The semiconductor lasers 10a to 10c each emit laser light in blue of a wavelength of 450 nm with an output of 1 W as excitation light.

However, the wavelength of the excitation light emitted from each of the semiconductor lasers 10a to 10c may be any wavelength included in a blue light region, and may be selected as appropriate in accordance with the excitation wavelength of the phosphor. That is, it is only required that the excitation light is visible light in blue. Also, any number and outputs of the semiconductor lasers 10a to 10c may be selected as appropriate in accordance with the specifications of the light-emitting device 100.

Note that although not depicted in (a) of FIG. 1, a power supply system for operating the semiconductor lasers 10a to 10c is connected to the semiconductor lasers 10a to 10c. Also, to dissipate heat generated at the time of operation of the semiconductor lasers 10a to 10c, a heat dissipation mechanism such as a heat sink or cooling jig may be provided to the semiconductor lasers 10a to 10c.

Also, the excitation light source according to one mode of the present invention may be any that can emit excitation light in blue, and may not be necessarily limited only to a semiconductor laser. By way of example, a blue LED which emits blue light can also be used as an excitation light source.

The three optical fibers 11a to 11c are members provided to guide laser lights emitted from the respective semiconductor lasers 10a to 10c. The optical fibers 11a to 11c are provided so as to correspond to the semiconductor lasers 10a to 10c, respectively. The laser lights emitted from the respective semiconductor lasers 10a to 10c enter an incident end of the optical fibers 11a to 11c.

The bundle fiber 12 is a bundle of the three optical fibers 11a to 11c on an exit end side. Also, an exit end of the bundle fiber 12 is connected to the ferrule 13.

The ferrule 13 is a member which retains the exit end of the bundle fiber 12. Note that the ferrule 13 may have a plurality of holes formed to allow the exit end of the bundle fiber 12 to be inserted therein. With the ferrule 13 provided, the exit end of the bundle fiber 12 is opposed to an excitation light radiation surface (a surface to which laser lights are radiated) of the light-emitting unit 1 in a predetermined orientation.

In this manner, the laser lights emitted from the semiconductor lasers 10a to 10c are emitted from the exit end of the bundle fiber 12, and radiated onto the excitation light radiation surface of the light-emitting unit 1. Then, with the phosphor included in the light-emitting unit 1 excited by the laser lights, a fluorescence having a wavelength longer than that of the laser light (for example, a fluorescence in yellow) is emitted from the phosphor.

Therefore, as described above, the laser lights in blue emitted from the semiconductor lasers 10a to 10c and the fluorescence in yellow emitted from the phosphor are mixed, thereby acquiring illumination light in white. This illumination light in white is emitted toward the lens 16 from a surface opposite to the excitation light radiation surface of the light-emitting unit 1.

In the following, the surface opposite to the excitation light radiation surface of the light-emitting unit 1 is referred to as an upper surface of the light-emitting unit 1. This upper surface may be understood as a surface on a fluorescence exit side of a phosphor layer 1a, which will be described further below. Also, the excitation light radiation surface of the light-emitting unit 1 is referred to as a lower surface of the light-emitting unit 1.

The ferrule fixing unit 14 is a member which fixes the ferrule 13. By way of example, the ferrule fixing unit 14 may be made of a metal material such as aluminum, copper, iron, or silver. Also, the fixing unit 15 is a member which fixes the ferrule fixing unit 14, the light-emitting unit 1, and the heat dissipating unit 18. Also as the material of the fixing unit 15, one similar to the material of the ferrule fixing unit 14 may be selected. Note that the ferrule fixing unit 14 and the fixing unit 15 can be integrally formed.

The lens 16 is a convex lens which transmits illumination light emitted from the upper surface of the light-emitting unit 1. A fluorescence transmitted from the lens 16 is emitted to the outside of the light-emitting device 100. In other words, the lens 16 is an optical transmission system which transmits illumination light to a desired direction.

Note that an optical member other than a convex lens can be used as the optical transmission system. By way of example, an optical transmission system can be configured of a reflector (concave lens). Also, a reflector and a convex lens can be combined to configure an optical transmission system.

The lens fixing unit 17 is a member which fixes the lens 16. Note that the lens fixing unit 17 also fixes the fixing unit 15 in the present embodiment. Thus, with reference to (a) of FIG. 1, heat generated at the light-emitting unit 1 is conducted via the heat dissipating unit 18 and the fixing unit 15 to the lens fixing unit 17.

Therefore, to effectively dissipate the heat, the lens fixing unit 17 is preferably formed by using a material excellent in thermal conductivity (such as aluminum). By way of example, the lens fixing unit 17 may be formed of black anodized aluminum.

The heat dissipating unit 18 is a member which dissipates heat generated at the light-emitting unit 1. The heat dissipating unit 18 is provided so as to cover side surfaces of the light-emitting unit 1. As with the lens fixing unit 17, the heat dissipating unit 18 is also preferably formed by using a material excellent in thermal conductivity. For example, the heat dissipating unit 18 may be formed of a metal material such as aluminum, copper, iron, or silver.

Next, with reference to (b) of FIG. 1, the structure of the light-emitting unit 1 is described. The light-emitting unit 1 includes the phosphor layer 1a and an excitation light distribution control unit 1b. This phosphor layer 1a may be understood as a wavelength conversion member.

In the light-emitting unit 1, the phosphor layer 1a is arranged on an upper side (that is, in a direction from a lower surface to an upper surface) of the excitation light distribution control unit 1b. Here, a lower surface of the phosphor layer 1a may be understood as an excitation light radiation surface of the phosphor layer 1a. Therefore, the phosphor layer 1a is arranged at a position closer to the lens 16 compared with the excitation light distribution control unit 1b. Also, the excitation light distribution control unit 1b is arranged at a position closer to the exit end of the bundle fiber 12 compared with the phosphor layer 1a.

Note in (b) of FIG. 1 that laser lights emitted from the semiconductor lasers 10a to 10c are referred to as laser light L1 and a fluorescence emitted from the phosphor included in the phosphor layer 1a is referred to as a fluorescence L2. As depicted in (b) of FIG. 1, the excitation light distribution control unit 1b receives the laser light L1 prior to the phosphor layer 1a.

Note that a region on the lower surface of the excitation light distribution control unit 1b to which the laser light L1 is radiated is referred to as an excitation light radiation region AP. The excitation light radiation region AP may be, for example, a circular region with a diameter of 1 mm. The size of the excitation light radiation region AP corresponds to a spot diameter of the laser light L1 emitted from the semiconductor lasers 10a to 10c.

The laser light L1 may thus be understood as spot light radiated onto a part of the region on the lower surface of the excitation light distribution control unit 1b. And, the laser light L1 passes through the excitation light distribution control unit 1b to be radiated onto the lower surface of the phosphor layer 1a.

Next, with the laser light L1 radiated onto the lower surface of the phosphor layer 1a, the fluorescence L2 is emitted from the lower surface of the phosphor layer 1a. As a result, illumination light with the laser light L1 and the fluorescence L2 mixed is emitted from the upper surface of the phosphor layer 1a toward the lens 16. Note that a region on the upper surface of the phosphor layer 1a from which illumination light is emitted is referred to as a light-emitting region BP.

As described above, in the light-emitting unit 1, the laser light L1 is radiated onto the excitation light radiation region AP positioned on the lower surface of the excitation light distribution control unit 1b, and illumination light including fluorescence L2 is emitted from the light-emitting region BP positioned on the upper surface of the phosphor layer 1a.

In other words, in the light-emitting unit 1, the surface onto which the laser light L1 (excitation light) is mainly radiated and the surface from which the fluorescence L2 is mainly emitted to the outside are opposed to each other. The structure of the light-emitting unit 1 is referred to as a transmissive structure.

The phosphor layer 1a is a member formed of a small-gap phosphor plate, and does not contain glass, resin, or the like. The fluorescence substance (phosphor) included in the phosphor layer 1a may be a monocrystalline or polycrystalline garnet-based phosphor. By using this garnet-based phosphor, the phosphor layer 1a not containing glass, resin, or the like and formed of a small-gap phosphor plate can be achieved.

First, the definition of the term “small-gap phosphor plate” is described. The small-gap phosphor plate means a phosphor plate in which a gap that is present inside has a width (hereinafter referred to as a gap width) equal to or shorter than one tenths of a wavelength of the visible light. More specifically, in the present embodiment, the gap width is equal to or longer than 0 nm and equal to or shorter than 40 nm. That is, when the gap width is represented as a sign t, 0 nm≤t≤40 nm holds. Note that the “small-gap phosphor plate” may be referred to as a “small-gap phosphor member”.

Note that, according to the above definition, the meaning of the term “small-gap phosphor plate” includes not only a phosphor plate with gaps (0 nm<t≤40 nm) but also a phosphor plate without gaps (t=0 nm). That is, in one embodiment of the present invention, the term “small-gap” includes a meaning “a gap is not present”.

Also, the above “gap” means an interstice between crystals in the phosphor plate (in other words, grain boundary). By way of example, the gap is a cavity where only air is present inside. However, some kind of foreign matter (example: such as alumina, which is a material of the phosphor plate) may enter the inside of the gap.

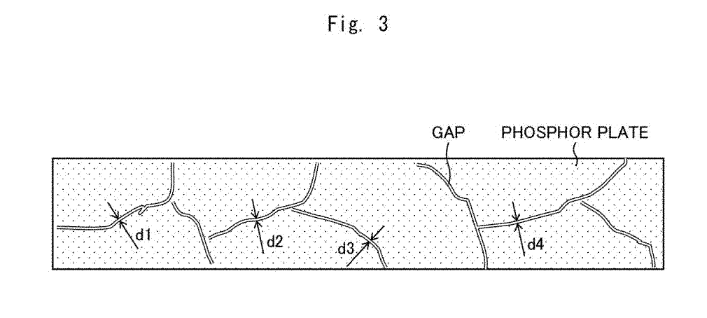

Also, the above “gap width” means a maximum value of the distance between adjacent crystals (crystalline grains) in the phosphor plate. FIG. 3 is a schematic diagram for describing a gap width in a phosphor plate (small-gap phosphor plate) according to the present embodiment. In FIG. 3, distances d1 to d4 are depicted as distances between adjacent crystals. For example. among the distances d1 to d4, if the distance d1 is a maximum distance, this distance d1 is a gap width.

Note that, to measure the above distances d1 to d4, it is only required that after a section of the phosphor plate is cut out, an observation image of that section is acquired by measuring equipment such as an optical microscope, scanning electron microscope (SEM), or transmission electron microscope (TEM). By analyzing the observation image, the distances d1 to d4 can be measured. That is, this allows a gap width to be measured.

And, as a result of the study by the inventors of the present application, in the small-gap phosphor plate, when the gap width is equal to or shorter than 40 nm, it has been confirmed that a scattering (internal scattering) effect on the laser light L1 and the fluorescence L2 does not occur at all or is extremely less prone to occur.

The length of the gap width as the above 40 nm is a length equal to or shorter than the order of one tenths of the wavelength of the excitation light (for blue light: 420 to 490 nm) and the wavelength of the phosphor (a wavelength longer than the excitation light). The above result of the study matches a general remark that, when light is radiated to a scatterer, Mie scattering does not occur when the size of the scatterer is equal to or shorter than the order of one tenths of the light. The above scattering effect does not occur at all or is very difficult to occur in the small-gap phosphor plate.

Therefore, when the light-emitting device is configured by using the phosphor layer 1a formed of a small-gap phosphor plate, color irregularity occurs in the illumination light emitted from the light-emitting device.

Here, a single crystal means a crystal in which the direction of the crystallographic axis is invariant at every position in the crystal. Also, a polycrystal means a crystal configured of a plurality of single crystals. Note that each single crystal included in the polycrystal is oriented to the direction of an individual crystallographic axis. Thus, the direction of the crystallographic axis can be varied in accordance with the position in the polycrystal.

Also, in the polycrystal, an interface is present between adjacent single crystals. This interface is referred to as a grain boundary (crystal grain boundary).

When the phosphor layer 1a is formed by using a polycrystalline phosphor, grain boundaries are present in the phosphor layer 1a. Thus, the gap width t in the phosphor layer 1a is longer than 0 nm and equal to or shorter than 40 nm. That is, in the case of the polycrystal, the relation of 0 nm<t≤40 nm is satisfied. Also, a method of manufacturing a polycrystalline phosphor plate will be described further below.

On the other hand, when the phosphor layer 1a is formed by using a monocrystalline phosphor, a grain boundary is not present in the phosphor layer 1a. Thus, the gap width t in the phosphor layer 1a is 0 nm. That is, in the case of the single crystal, the relation of t=0 nm is satisfied. Also, a method of manufacturing a monocrystalline phosphor plate will be described further below.

As described above, depending on the presence or absence of grain boundaries in the phosphor layer 1a (in other words, the value of the gap width t), it can be distinguished whether the phosphor configuring the phosphor layer 1a is a single crystal or polycrystal. Note in the small-gap phosphor plate that the phosphor configuring the small-gap phosphor plate can be distinguished as a single crystal also when the value of the gap width t is sufficiently small to the extent of being regarded as t=0 nm.

Also, as described above, the monocrystalline phosphor has a small gap width t compared with that of the polycrystalline phosphor. Thus, the monocrystalline phosphor has high thermal conductivity compared with the polycrystalline phosphor. Thus, the monocrystalline phosphor tends to dissipate heat compared with the polycrystalline phosphor.

However, the polycrystalline phosphor also has a very small gap width t of 0 nm<t≤40 nm in the present embodiment, and thus has high thermal conductivity compared with conventional phosphors. Also, if the gap width t is very small, even the polycrystalline phosphor can have thermal conductivity approximately equivalent to that of the monocrystalline phosphor.

Therefore, when a grain boundary is not present in the phosphor layer 1a, a temperature increase of the phosphor layer 1a can be inhibited compared with the case in which a grain boundary is present in the phosphor layer 1a, thereby allowing an improvement in luminous efficiency of the phosphor layer 1a. In other words, the use of the monocrystalline phosphor can achieve the light-emitting device 100 which outputs illumination light with higher luminance compared with the case of using the polycrystalline phosphor.

And, the garnet-based phosphor is excellent in both luminous efficiency and heat dissipation properties, and is thus suitable for improving the performance of the light-emitting device 100. In the present embodiment, as the garnet-based phosphor, a YAG phosphor represented as a chemical formula of (Y, Lu, Gd)₃(Al, Ga)₅O₁₂:Ce is used. The YAG phosphor emits a fluorescence (fluorescence L2) in yellow having a peak wavelength of approximately 550 nm.

However, the garnet-based phosphor according to one mode of the present invention may not be limited only to the YAG phosphor. By way of example, a gadolinium aluminum gallium garnet (GAGG) phosphor or a lutetium aluminum garnet (LuAG) phosphor may be used as a garnet-based phosphor. Note that the garnet-based phosphor is preferably doped with cerium (Ce) as a luminescence center.

However, in view of luminous efficiency and heat dissipation properties, the use of the YAG phosphor is particularly preferable. In particular, by using the YAG monocrystalline phosphor, the performance of the light-emitting device can be particularly suitably improved.

Meanwhile, the monocrystalline or polycrystalline garnet-based phosphor is known to have extremely low light scattering properties. Therefore, the phosphor layer 1a is also a member with very low light scattering properties.

In view of this point, the inventors of the present application conducted an experiment to confirm light scattering properties of each of a YAG monocrystalline phosphor and a YAG polycrystalline phosphor. Specifically, the inventors of the present application conducted an experiment of using a YAG monocrystalline phosphor and a YAG polycrystalline phosphor to form respective phosphor layers and measuring a haze value on a flat surface of each phosphor layer.

Here, the haze value is an index indicating a ratio of diffuse transmittance with respect to the overall light transmittance of light incident to a certain surface. Therefore, it may be understood that as the haze value is smaller, light scattering properties are low.

As a result of the experiment, it was confirmed that the haze value of the YAG monocrystalline phosphor on a flat surface is 4.5%. It was also confirmed that the haze value of the YAG polycrystalline phosphor on a flat surface is 4.6%.

In this manner, it was confirmed that the YAG monocrystalline phosphor and the YAG polycrystalline phosphor each have a very low haze value of approximately 5% or smaller. In other words, it was confirmed that the YAG monocrystalline phosphor and the YAG polycrystalline phosphor have very low light scattering properties. Therefore, it may be understood that the phosphor layer 1a are members with very low scattering properties, hardly scattering light.

It was also confirmed that the YAG monocrystalline phosphor and the YAG polycrystalline phosphor have haze values approximately equivalent to each other. Therefore, it can be said that no significance difference in the degree of light scattering properties exists between the YAG monocrystalline phosphor and the YAG polycrystalline phosphor. Thus, a phosphor layer with less inner scattering is formed by using either of the YAG monocrystalline phosphor and the YAG polycrystalline phosphor. Also, the phosphor layer emits a fluorescence with high luminance.

Next, an example of the method of manufacturing the phosphor layer 1a configured of a polycrystal (polycrystalline phosphor plate) is described below. First, with oxide powder of a submicron size as a material, phosphor raw material powder is created by a solution phase method or solid phase method. For example, when the phosphor raw material powder is a YAG phosphor, the oxide is yttrium oxide, aluminum oxide, ceric oxide, and the like. Then, the phosphor raw material powder is molded with a metal mold for vacuum sintering.

By using the above method, the phosphor layer 1a having the gap width t satisfying 0 nm<t≤40 nm can be acquired. As described above, the phosphor layer 1a has the shorter gap width t compared with that of the conventional phosphor layers, and thus has high thermal conductivity.

Thus, the temperature of the phosphor layer 1a is hard to increase even high-density excitation light is radiated. Therefore, a decrease in efficiency of the phosphor configuring the phosphor layer 1a can be inhibited. Therefore, a light-emitting device with high luminance and high efficiency can be provided.

Furthermore, according to the above method, the phosphor layer 1a is formed to have a shape close to a product, thereby allowing a small material loss and reduction in time required for process. That is, according to the above method, mass productivity of polycrystalline phosphor plates can be improved.

Also, examples of the method of manufacturing the phosphor layer 1a configured of a single crystal (monocrystalline phosphor plate) include a solution phase method, for example, the CZ method. Specifically, first, oxide powder is mixed and powdered by dry blending or the like, and the mixed powder is put into a crucible for heating, thereby fabricating a melt. Next, phosphor seed crystals are prepared. The phosphor seed crystal is brought into contact with the melt, and is then lifted as being rotated. Here, the lifting temperature is set on the order of 2000° C. This can grow a phosphor monocrystalline ingot of, for example, a <111> direction. Then, the monocrystalline ingot is cut out to a desired size. Note that a monocrystalline plate can be cut out also in a <001> or <110> direction, for example, depending on how to cut out a monocrystalline ingot.

According to the above method, the monocrystalline ingot is created from a melt at a temperature equal to or higher than a melting point of the phosphor, and thus has high crystallinity. That is, defects are decreased. This improves the temperature characteristics of the phosphor layer 1a and inhibits degradation of efficiency due to a temperature increase.

In addition, the monocrystalline ingot acquired by the above method has no gap (because the gap width t=0 nm), and thus has further high thermal conductivity compared with the phosphor layer 1a formed of a polycrystal. The thermal conductivity of the monocrystalline ingot is on the order of, for example, 10 W/m·K. Thus, a temperature increase of the phosphor layer 1a can be inhibited even when high-density excitation light is radiated.

Note that the phosphor layer 1a may be formed so as to have any sectional shape (rectangular or circular shape) in accordance with the specifications of the light-emitting device 100. By way of example, the phosphor layer 1a in the present embodiment is formed so as to have a square sectional shape with each length of 10 mm. The thickness of the phosphor layer 1a in the present embodiment has a value, although not particularly limited, on the order of 100 m to 0.5 mm.

Next, the excitation light distribution control unit 1b is described. The excitation light distribution control unit 1b may be understood as a member provided to compensate for very low light scattering properties of the phosphor layer 1a. As described below, the excitation light distribution control unit 1b is a member which controls light distribution of the laser light L1 and guides the distribution-controlled laser light L1 to the inside of the phosphor layer 1a.

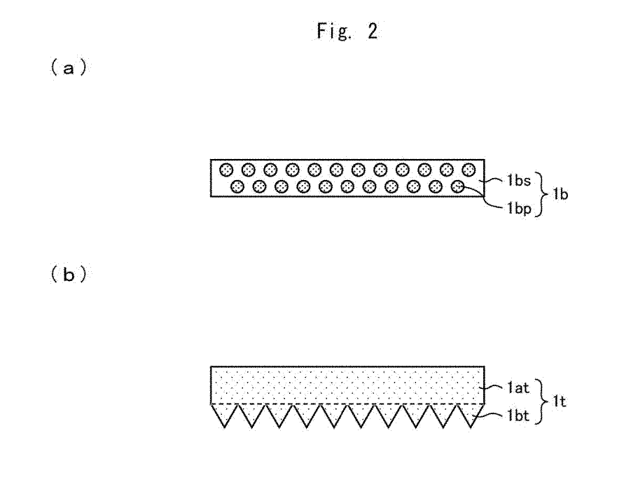

Here, a specific example of the structure of the excitation light distribution control unit 1b is described with reference to (a) and (b) of FIG. 2. (a) and (b) of FIG. 2 are diagrams each depicting the specific example of the structure of the excitation light distribution control unit 1b.

First, the structure of (a) of FIG. 2 is described. (a) of FIG. 2 depicts the structure when the excitation light distribution control unit 1b is provided separately from the phosphor layer 1a. The excitation light distribution control unit 1b includes a sealing layer 1bs and scatterer particles 1bp.

The sealing layer 1bs is a layer (thin film) for sealing the scatterer particles 1bp inside. The sealing layer 1bs is formed of a transparent material. The sealing layer 1bs may be formed of glass (such as silica glass). With the sealing layer 1bs formed of glass, it is possible to improve thermal conductivity of the excitation light distribution control unit 1b.

Note that when the sealing layer 1bs is formed of glass, it is only required that the scatterer particles 1bp are deposited on a lower surface of the phosphor layer 1a by a known method such as screen printing. Next, a glass material before curing is applied to the lower surface of the phosphor layer 1a where the scatterer particles 1bp are deposited. Then, by curing the glass material, the glass having the scatterer particles 1bp contained therein (that is, the sealing layer 1bs) can be formed.

However, the material of the sealing layer 1bs is not limited only to glass. By way of example, the sealing layer 1bs may be formed of resin (such as silicone or acrylic). In this case, the sealing layer 1bs can be formed by preparing resin with the scatterer particles 1bp dispersed therein and applying the resin to the lower surface of the phosphor layer 1a.

Note that the thickness of the sealing layer 1bs may be determined as appropriate in accordance with the size of the excitation light radiation region AP. By way of example, the thickness of the sealing layer 1bs may have a value on the order of 10 μm to 100 μm. Note that the thickness of the sealing layer 1bs (the thickness of the excitation light distribution control unit 1b) is preferably formed to be thin compared with the phosphor layer 1a. In consideration of this point, the thickness of the sealing layer 1bs is more preferably equal to or longer than 10 μm and equal to or shorter than 50 μm.

The scatterer particles 1bp are a member having a function of scattering the laser light L1. The scatterer particles 1bp are alumina particles on the order of, for example, several μm. Part of the laser light L1 scattered by the excitation light distribution control unit 1b heads toward the lower surface of the phosphor layer 1a.

As described above, in the case of (a) of FIG. 2, provision of the scatterer particles 1bp achieves the excitation light distribution control unit 1b. Note that, as depicted in (b) of FIG. 2, while the structure of the excitation light distribution control unit is not limited only to the structure of (a) of FIG. 2, the structure of (a) of FIG. 2 is exemplarily presented for description in each embodiment unless otherwise specified, for the sake of simplification.

Next, the structure of (b) of FIG. 2 is described. (b) of FIG. 2 depicts the case in which the excitation light distribution control unit is provided integrally with the phosphor layer. Here, for distinction from the structures of (a) of FIG. 1 described above and (a) of FIG. 2, a light-emitting unit of (b) of FIG. 2 is represented as a light-emitting unit 1t.

The light-emitting unit 1t is a member formed by processing the above-described phosphor layer 1a. Specifically, the light-emitting unit it is formed by performing surface finishing (for example, etching or polishing) on the lower surface of the phosphor layer 1a.

The light-emitting unit 1t includes a phosphor layer 1at and a scattering layer 1bt (concavo-convex shape). The phosphor layer 1at is a phosphor layer having a flat surface, and has a function similar to that of the above phosphor layer 1a. On the other hand, the scattering layer 1bt is a phosphor layer having a surface with minute concavo-convex portions formed on its lower surface. The concavo-convex portions function as a scattering mechanism which scatters the laser light L1.

Here, to suitably scatter the laser light L1 in the concavo-convex portion, an average space (pitch) of adjacent concave portions and convex portions in the concavo-convex portion is provided so as to be longer than the peak wavelength (450 nm) of the laser light L1. The pitch may be, for example, equal to or longer than 1 μm. Note that the concavo-convex shape may be formed not randomly but, for example, the concave portions and convex portions may be cyclically formed. In this case, the cycle of the concave portions and convex portions serves as the pitch.

The structure of (b) of FIG. 2 may be understood as a structure in which the phosphor layer also has a function of an excitation light distribution control unit. In other words, it may be understood that (b) of FIG. 2 depicts the structure in which, as an excitation light distribution control unit, a concavo-convex shape is formed on an excitation light radiation surface of the phosphor layer. In this manner, the scattering layer 1bt functions as an excitation light distribution control unit which controls light distribution of the laser light L1 and guides the laser light L1 to the inside of the phosphor layer 1at.

Note that on the lower surface of the scattering layer 1bt, an anti-reflection (AR) coat which inhibits reflection of the laser light L1 may be formed in a region corresponding to the excitation light radiation region AP. This allows the laser light L1 radiated to the excitation light radiation region AP to be more suitably guided to the inside of the phosphor layer 1at.

### Comparative Examples

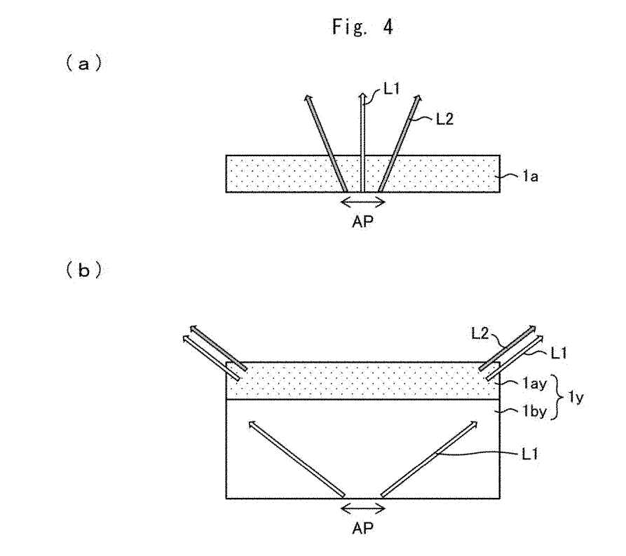

Here, prior to description of the effects of the light-emitting unit 1 (in other words, the effects of the light-emitting device 100), comparative examples are described. (a) and (b) of FIG. 4 are diagrams each depicting a comparative example of the light-emitting unit 1.

(a) of FIG. 4 is a diagram depicting a first comparative example. In the first comparative example, the excitation light distribution control unit 1b is excluded from the light-emitting unit 1. Here, in the first comparative example, the case is considered in which the laser light L1 is radiated to the phosphor layer 1a.

As described above, since light scattering properties in the phosphor layer 1a are very low, the laser light L1 is not scattered inside the phosphor layer 1a. Therefore, the laser light L1 is emitted to the outside of the light-emitting device while the direction of being emitted from the semiconductor lasers 10a to 10c is kept. In other words, the laser light L1 is emitted to the outside of the light-emitting device while having a specific directivity.

On the other hand, the fluorescence L2 occurs in the entire region of the lower surface of the phosphor layer 1a corresponding to the excitation light radiation region AP, and thus does not have a specific directivity. Therefore, the light distribution of the laser light L1 and that of the fluorescence L2 cannot be matched each other, thereby causing color irregularity of illumination light. In this manner, when the excitation light distribution control unit 1b is not provided, a problem arises in that color irregularity of illumination light cannot be inhibited.

Also, (b) of FIG. 4 is a diagram depicting a second comparative example. Here, a light-emitting unit in the second comparative example is referred to as a light-emitting unit 1y. The light-emitting unit 1y includes a first layer 1ay and a second layer 1by.

The first layer 1ay is a wavelength conversion member including scatterer particles (for example, alumina) and a phosphor (for example, a YAG phosphor). The first layer 1ay may be formed with the scatterer particles and the phosphor dispersed in resin. The first layer 1ay (more specifically, the phosphor included in the first layer 1ay) receives the laser light L1 and emits the fluorescence L2.

The second layer 1by is a layer provided on a lower surface of the first layer 1ay, and has a function of diffusing the laser light L1. Also, the second layer 1by has a sufficient thickness compared with the first layer 1ay. The laser light L1 incident to a lower surface of the second layer 1by is diffused inside the second layer 1by, and then reaches the entire lower surface of the first layer 1ay.

Then, the laser light L1 reaching the entire lower surface of the first layer 1ay is further scattered by the scatterer particles included in the first layer 1ay. Therefore, in the light-emitting unit 1y, the light-emitting region is distributed to the entire upper surface of the first layer 1ay or a region wider than that.

That is, in the light-emitting unit 1y, while the provision of the first layer 1ay and the second layer 1by inhibits color irregularity of illumination light, in compensation for that, a spot property of illumination light is lost. Therefore, in the light-emitting unit 1y, a problem arises in that high-luminance illumination light cannot be acquired.

### (Effects of Light-Emitting Device 100)

In the light-emitting device 100 of the present embodiment, the light-emitting unit 1 includes the phosphor layer 1a and the excitation light distribution control unit 1b. As described above, the excitation light distribution control unit 1b can control the light distribution of the laser light L1 and guide the laser light L1 to the inside of the phosphor layer 1a.

Therefore, unlike the first comparison example described above, the light-emitting unit 1 can distribute the laser light L1 in a wider range, and can thus match the light distribution of the laser light L1 with the light distribution of the fluorescence L2. In this manner, the provision of the excitation light distribution control unit 1b allows color irregularity of illumination light to be inhibited.

Also, as described above, the laser light L1 is hardly scattered inside the phosphor layer 1a. Therefore, unlike the second comparative example described above, while inhibiting color irregularity of illumination light, the light-emitting unit 1 can keep the spot property of the illumination light. That is, in the light-emitting unit 1, a small-size light-emitting region BP can be achieved.

In particular, by making the thickness of the excitation light distribution control unit 1b sufficiently thin, the size of the light-emitting region BP can be made approximately equivalent to the size of the excitation light radiation region AP. Thus, since the illumination light is not distributed in a wide range, high-luminance illumination light can also be acquired.

Next, a further effect of the light-emitting device 100 is described. When the excitation light is laser light, the laser light has high power density per unit area, and it is concerned that there is a possibility of damaging safety of the light-emitting device when the laser light is emitted from the light-emitting device 100 without being scattered.

However, in the light-emitting device 100, since the excitation light distribution control unit 1b is provided, the laser light can be scattered. For this reason, the power density of the laser light per unit area can be decreased. Therefore, the laser light with higher safety can be emitted as part of white light to the outside of the light-emitting device 100. In this manner, according to the light-emitting device 100 of the present embodiment, safety of the light-emitting device can also be enhanced.

### Second Embodiment

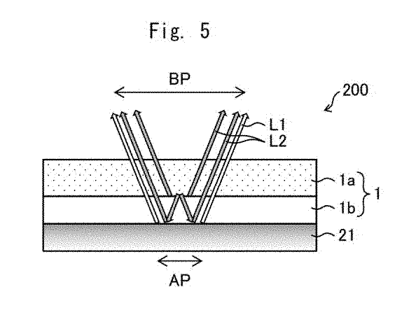

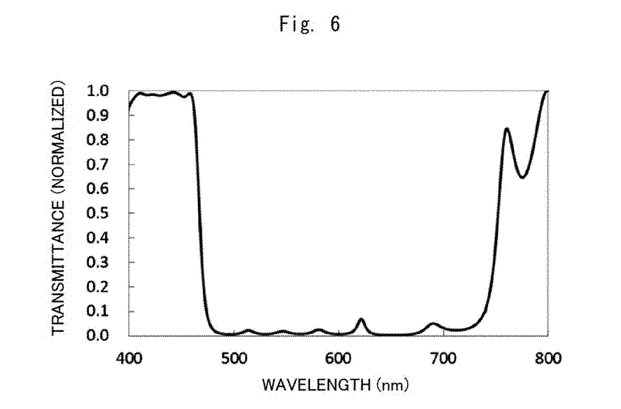

A second embodiment of the present invention is described based on FIG. 5 and FIG. 6 as follows. Note that, for convenience of description, a member having the same function as that of the member described in the above embodiment is provided with the same reference character and description of that member is omitted.

A light-emitting device 200 of the present embodiment is configured by adding a dichroic mirror 21 to the light-emitting device 100 of the first embodiment. FIG. 5 is a diagram schematically depicting the structure of the periphery of the light-emitting unit 1 included in the light-emitting device 200.

The dichroic mirror 21 is an optical member having a function of transmitting light in a predetermined wavelength range and reflecting light other than that in the wavelength range. The dichroic mirror 21 may be formed by using, for example, a dielectric multilayer film. As the dielectric multilayer film, for example, a dielectric multilayer film of SiO₂/TiO₂ can be used.

The dichroic mirror 21 has an optical property of transmitting the laser light L1 in blue and reflecting the fluorescence L2 in yellow. FIG. 6 is a graph depicting one example of the optical property of the dichroic mirror 21 of the present embodiment.

In the graph of FIG. 6, the horizontal axis represents optical wavelength, and the vertical axis represents optical transmittance. Note that the optical transmittance represents a value normalized by taking 1 as a maximum value.

With reference to FIG. 6, it can be understood that the dichroic mirror 21 (i) allows light in a wavelength range on the order of 460 nm or shorter to be suitably transmitted, and (ii) allows light in a wavelength range on the order of 470 nm to 750 nm to be suitably reflected.

Therefore, the dichroic mirror 21 has a function of transmitting the laser light L1 in blue having a wavelength of 450 nm and reflecting the fluorescence L2 in yellow having a peak wavelength of 550 nm. Note that the dichroic mirror 21 is designed so that optical absorptivity is very low, which does not adversely affect an improvement in optical use efficiency, which will be described further below.

Here, with reference to FIG. 5 again, an advantage of the dichroic mirror 21 is described. As depicted in FIG. 5, the dichroic mirror 21 is provided so as to cover the lower surface of the excitation light distribution control unit 1b. This makes the laser light L1 pass through the dichroic mirror 21 to reach the lower surface of the excitation light distribution control unit 1b.

Note that the dichroic mirror 21 can be more easily provided to the lower surface of the excitation light distribution control unit 1b (in the case of (b) of FIG. 2, the scattering layer 1bt) when the structure of the light-emitting unit of (b) of FIG. 2 described above is adopted, compared with the structure of the light-emitting unit of (a) of FIG. 2.

And, part of the fluorescence L2 emitted inside the phosphor layer 1a heads toward a lower side (in a direction from the phosphor layer 1a toward the excitation light distribution control unit 1b). The provision of the dichroic mirror 21 allows the fluorescence L2 toward the lower side to be reflected by an upper surface of the dichroic mirror 21 and headed toward an upper side of the phosphor layer 1a.

Therefore, the provision of the dichroic mirror 21 makes a more amount of the fluorescence L2 emitted from the upper side of the phosphor layer 1a (usable as part of illumination light), and the luminance of the illumination light can thus be improved.

In this manner, the provision of the dichroic mirror 21 can increase the light quantity of the fluorescence L2 that can be used as part of illumination light and can thus decrease the size of the phosphor layer 1a. In particular, the thickness of the phosphor layer 1a can be made thin. The decrease of the size of the phosphor layer 1a can reduce the amount of the phosphor required for manufacture of the phosphor layer 1a and can thus reduce manufacturing cost of the phosphor layer 1a.

Note that while the structure is exemplarily depicted in FIG. 5 in which the dichroic mirror 21 is provided to the lower surface of the excitation light distribution control unit 1b, the position where the dichroic mirror 21 is provided is not necessarily limited to this.

Specifically, the dichroic mirror 21 may be provided on the upper surface of the excitation light distribution control unit 1b. In this case, the dichroic mirror 21 is arranged so as to be interposed between the phosphor layer 1a and the excitation light distribution control unit 1b in a vertical direction.

That is, in the light-emitting device according to one mode of the present invention, it is only required that the dichroic mirror 21 is provided to the phosphor layer 1a on an incident side of the laser light L1. This is because, if the positional relation is satisfied, the fluorescence L2 toward the lower side of the phosphor layer 1a can be reflected by the dichroic mirror 21.

### Third Embodiment

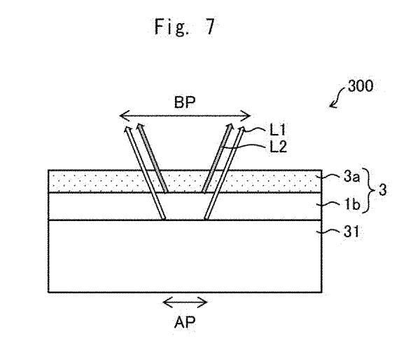

A third embodiment of the present invention is described based on FIG. 7 as follows. A light-emitting device 300 of the present embodiment is configured by (i) replacing the light-emitting unit 1 by a light-emitting unit 3 and (ii) adding a substrate 31, in the light-emitting device 100 of the first embodiment. FIG. 7 is a diagram schematically depicting the structure of the periphery of the light-emitting unit 3 included in the light-emitting device 300.

The light-emitting unit 3 of the present embodiment is a member with the phosphor layer 1a in the light-emitting unit 1 of the first embodiment replaced by a phosphor layer 3a. Note that the phosphor layer 3a is a member having a function similar to that of the phosphor layer 1a but is provided, for convenience, with a different member number for distinction from the phosphor layer 1a.

The phosphor layer 3a is different from the phosphor layer 1a in having a thickness sufficiently thin compared with the phosphor layer 1a. Specifically, the phosphor layer 3a may be formed so as to have a thickness on the order of 10 μm to 100 μm. As described above, application of the sufficiently-thin phosphor layer 3a reduces manufacturing cost of the phosphor layer.

However, when the thickness of the phosphor layer 3a is made very thin, it is concerned that the mechanical strength of the phosphor layer 3a is decreased. Therefore, it is concerned that the risk that the phosphor layer 3a has a risk of being easily cracked when a downward external force is applied to the phosphor layer 3a. Thus, in the present embodiment, to prevent the phosphor layer 3a from being easily cracked, the substrate 31 which supports the light-emitting unit 3 is provided.

The substrate 31 is a member which supports the light-emitting unit 3. Specifically, the substrate 31 supports the lower surface of the excitation light distribution control unit 1b. Therefore, the phosphor layer 3a is indirectly supported to the substrate 31 via the excitation light distribution control unit 1b.

The provision of the substrate 31 can prevent a crack in the phosphor layer 3a from occurring even when the very thin phosphor layer 3a is used. This facilitates treatment (handling) of the light-emitting device 300.

The substrate 31 has a light-transmitting property so as to allow the laser light L1 to be transmitted. Also the substrate 31 preferably has high thermal conductivity so as to be able to efficiently dissipate heat generated at the light-emitting unit 3. As a material of the substrate 31, by using sapphire, the substrate 31 that is transparent and has high thermal conductivity can be achieved.

Note that in the substrate 31, a portion corresponding to the excitation light radiation region AP is preferably bonded to the lower surface of the excitation light distribution control unit 1b by using a transparent bonding agent. This can prevent the laser light L1 radiated toward the substrate 31 and headed toward the excitation light distribution control unit 1b in the excitation light radiation region AP from being reflected or absorbed on an interface between the substrate 31 and the excitation light distribution control unit 1b.

However, in the substrate 31, a portion not corresponding to the excitation light radiation region AP is a portion where the laser light L1 may not necessarily be transmitted, and thus may be boned to the lower surface of the excitation light distribution control unit 1b by using an opaque bonding agent.

Note that the dichroic mirror 21 described in the above second embodiment may be provided on an upper surface or lower surface of the substrate 31. This allows a reduction in luminance of illumination light to be inhibited even when the very thin phosphor layer 3a is used.

Note that the upper surface of the substrate 31 may be processed to form a concavo-convex shape on the upper surface. This concavo-convex shape may be a shape similar to the concavo-convex shape provided to the scattering layer 1bt of (b) of FIG. 2 described above. The provision of the concavo-convex shape on the upper surface of the substrate 31 allows the upper surface of the substrate 31 to function as an excitation light distribution control unit.

Also, on the lower surface of the substrate 31, an AR coat which inhibits reflection of the laser light L1 may be formed in a region corresponding to the excitation light radiation region AP. This allows the laser light L1 radiated to the excitation light radiation region AP to be more suitably guided to the inside of the phosphor layer 3a. Also, the dichroic mirror 21 described above may be provided on the upper surface of the substrate 31.

When the size of the substrate 31 is large, by achieving the excitation light distribution control unit in the above-described manner, an advantage that the excitation light distribution control unit can be more efficiently manufactured compared with the structures of (a) and (b) of FIG. 2 described above can be acquired.

### Fourth Embodiment

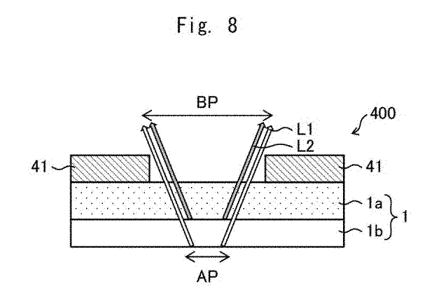

A fourth embodiment of the present invention is described based on FIG. 8 as follows. A light-emitting device 400 of the present embodiment is configured by adding a reflecting unit 41 (light shielding unit) to the light-emitting device 100 of the first embodiment. FIG. 8 is a diagram schematically depicting the structure of the periphery of a light-emitting unit 3 included in the light-emitting device 400.

The reflecting unit 41 is an optical member which reflects the laser light L1 and the fluorescence L2. The reflecting unit 41 is provided so as to cover a part of the upper surface of the phosphor layer 1a (that is, a surface on a fluorescence exit side of the phosphor layer 1a). Therefore, as depicted in FIG. 8, a portion of the upper surface of the phosphor layer 1a not covered with the reflecting unit 41 (which is also referred to as an opening on the upper surface of the phosphor layer 1a) corresponds to the light-emitting region BP.

The shape of the opening on the upper surface of the phosphor layer 1a may be any shape (for example, circular or rectangular shape). In other words, it is only required that part of the upper surface of the phosphor layer 1a is covered with the reflecting unit 41 so that the shape of the opening on the upper surface of the phosphor layer 1a may have a desired shape.

By way of example, the reflecting unit 41 may be formed of a metal material such as Al or Ag. Also, the reflecting unit 41 may be formed of a multilayer film of a dielectric. The reflecting unit 41 may be formed by using a known method for forming a thin film (for example, such as vapor deposition or sputtering) so as to cover a part of the upper surface of the phosphor layer 1a.

According to the light-emitting device 400 of the present embodiment, with the provision of the reflecting unit 41, the laser light L1 and the fluorescence L2 (that is, illumination light) are emitted only from the opening on the upper surface of the phosphor layer 1a to an upper part of the light-emitting unit 1.

That is, in accordance with the shape of the reflecting unit 41 which covers a part of the upper surface of the phosphor layer 1a, the shape of the opening on the upper surface of the phosphor layer 1a can be defined. Therefore, a light-emission pattern of illumination light corresponding to the shape of the opening on the upper surface of the phosphor layer 1a can be acquired.

Next, a further effect of the reflecting unit 41 is described. Here, the case is considered in which the excitation light distribution control unit 1b cannot sufficiently scatter the laser light L1. In this case, substantially as with the case of (a) of FIG. 4 described above, the light distribution of the laser light L1 cannot be matched with the light distribution of the fluorescence L2, and a problem arises in that color irregularity of illumination light occurs.

However, in the present embodiment, the area of the opening on the upper surface of the phosphor layer 1a can be defined by the reflecting unit 41, and thus the light-emitting region BP can be defined. Therefore, the reflecting unit 41 can be used as a member which restricts (narrows) the range in which the fluorescence L2 is emitted to the upper surface.

Therefore, even when the excitation light distribution control unit 1b cannot sufficiently scatter the laser light L1 (cannot sufficiently control the light distribution of the laser light L1), by providing the reflecting unit 41 so that the area of the opening on the upper surface of the phosphor layer 1a is sufficiently small, the light distribution of the fluorescence L2 can be matched with the light distribution of the laser light L1. Therefore, color irregularity of illumination light can be more suitably reduced.

In addition, the provision of the reflecting unit 41 allows an advantage that use efficiency of light (the laser light L1 and the fluorescence L2) is improved to be acquired. By way of example, part of the laser light L1 is reflected by the reflecting unit 41 and headed toward the phosphor layer 1a.

Therefore, the laser light L1 reflected by the reflecting unit 41 allows the phosphor layer 1a to be excited so as to generate the fluorescence L2. In this manner, the provision of the reflecting unit 41 allows the laser light L1 to be more efficiently used as excitation light.

Also, part of the fluorescence L2 is reflected by the reflecting unit 41 and is headed toward the upper surface of the phosphor layer 1a. Therefore, the fluorescence L2 can be more effectively used as part of illumination light. In this manner, the provision of the reflecting unit 41 improves optical use efficiency, and thus can improve luminance of illumination light.

### Modification Example

In the above fourth embodiment, the structure using the reflecting unit 41 as a light shielding unit is described. However, it is only required that the light shielding unit according to one mode of the present invention has a function of shielding light (not allowing transmission of light) and is not necessarily limited to the reflecting unit.

By way of example, in the fourth embodiment, the reflecting unit 41 may be replaced by an optical absorbing unit. The optical absorbing unit is an optical member which absorbs the laser light L1 and the fluorescence L2. As a material of the optical member, for example, carbon black may be used.

When the optical absorbing unit is used as the light shielding unit, a light-emission pattern of illumination light can be defined by the shape of the opening of the phosphor layer 1a, and color irregularity of illumination light can thus be reduced.

However, when the optical absorbing unit is used as the light shielding unit, use efficiency of light (the laser light L1 and the fluorescence L2) cannot be improved. From this point, as described in the fourth embodiment described above, it is particularly preferable that the reflecting unit 41 is used as a light shielding unit.

### Fifth Embodiment

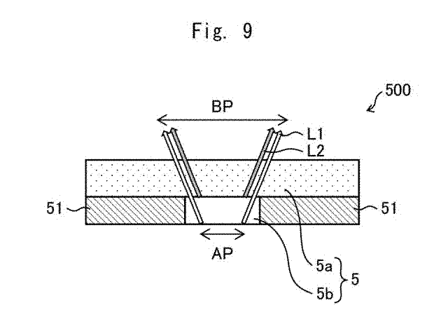

A fifth embodiment of the present invention is described based on FIG. 9 as follows. A light-emitting device 500 of the present embodiment is configured by (i) replacing the light-emitting unit 1 by a light-emitting unit 5 and (ii) adding a reflecting unit 51 (light-shielding unit), in the light-emitting device 100 of the first embodiment. FIG. 9 is a diagram schematically depicting the structure of the periphery of the light-emitting unit 5 included in the light-emitting device 500.

The light-emitting unit 5 includes a phosphor layer 5a and an excitation light distribution control unit 5b. Note that the phosphor layer 5a is a member similar to the phosphor layer 1a described above but a relative positional relation between the excitation light distribution control unit and the reflecting unit is different from that of the fourth embodiment described above. Thus, the phosphor layer in the present embodiment is provided, for convenience, with a different member number for distinction from the phosphor layer 1a, and is referred to as a phosphor layer 5a.

Also, the reflecting unit in the present embodiment is provided, for convenience, with a different member number for distinction from the reflecting unit 41, and is referred to as a reflecting unit 51. Note that, as described above, an optical absorbing unit may be used as a light shielding unit. In the present embodiment, the reflecting unit 51 is provided so as to cover a part of the lower surface of the phosphor layer 1a (that is, an excitation light radiation surface of the phosphor layer 1a).

The excitation light distribution control unit 5b is a member similar to the excitation light distribution control unit 1b described above. However, the excitation light distribution control unit 5b of the present embodiment is different from the excitation light distribution control unit 1b of the first embodiment in being provided only to a part of the lower surface of the phosphor layer 5a. Specifically, the excitation light distribution control unit 5b is provided to a portion of the lower surface of the phosphor layer 5a not covered with the reflecting unit 51 (also referred to as an opening on the upper surface of the phosphor layer 1a).

Note that when the excitation light distribution control unit 5b is achieved by the structure of (a) of FIG. 2, it is only required that a mask for screen printing is provided in a predetermined region of the lower surface of the phosphor layer 5a. By performing screen printing on the mask, the excitation light distribution control unit 5b can be selectively formed only in the predetermined region.

Also, when the excitation light distribution control unit 5b is achieved by the structure of (b) of FIG. 2, it is only required that a mask for photolithography is provided to a region other than the predetermined region of the lower surface of the phosphor layer 5a. By etching on the entire lower surface of the phosphor layer 5a, a concavo-convex shape (excitation light distribution control unit 5b) can be selectively formed only in the predetermined region.

In the light-emitting device 500 of the present embodiment, as depicted in FIG. 9, the shape of the opening on the lower surface of the phosphor layer 5a can be defined in accordance with the shape of the reflecting unit 51. Therefore, as with the fourth embodiment described above, a pattern of illumination light corresponding to the shape of the opening can be acquired.

Note in the present embodiment that the reflecting unit 51 is provided to the phosphor layer 5a on an incident side of the laser light L1, and thus the dichroic mirror 21 is not required to be provided. In addition, the reflecting unit 51 reflects a fluorescence toward a lower side of the fluorescence emitted from the phosphor layer 5a to cause the fluorescence to be headed again toward the phosphor layer 5a.

That is, in the present embodiment, as with the dichroic mirror 21, the reflecting unit 51 serves a function as an optical member which improves use efficiency of the fluorescence L2. In this manner, according to the light-emitting device 500 of the present embodiment, use efficiency of the fluorescence L2 can be improved without providing the dichroic mirror 21. Thus, by a relatively easy structure, high-luminance illumination light can also be acquired.

### [Conclusion]

A light-emitting device (100) according to a first mode of the present invention is a light-emitting device which emits excitation light (laser light L1) as part of illumination light, and includes an excitation light source (semiconductor lasers 10a to 10c) which emits the excitation light, which is visible light, a phosphor layer (1a) formed of a small-gap phosphor plate which emits a fluorescence (L2) upon reception of the excitation light emitted from the excitation light source, and an excitation light distribution control unit (1b) which controls light distribution of the excitation light and guides the excitation light to inside of the phosphor layer, and the small-gap phosphor plate is a phosphor plate in which a gap that is present inside has a width equal to or longer than 0 nm and equal to or shorter than one tenths of a wavelength of the excitation light.

According to the above structure, the excitation light with light distribution controlled by the excitation light distribution control unit can be guided to the inside of the phosphor layer. Then, upon receiving the fluorescence, the phosphor layer emits fluorescence. Here, as described above, since the phosphor layer is formed of a small-gap phosphor plate, light (the excitation light and the fluorescence) is hardly scattered inside the phosphor layer.

Therefore, the light distribution of the excitation light controlled by the excitation light distribution control unit approximately matches the light distribution of the fluorescence. That is, the light distribution of the excitation light can be matched with the light distribution of the fluorescence. Therefore, to the outside of the light-emitting device, illumination light (white light, more specifically, pseudo white light) with the excitation light and the fluorescence approximately uniformly mixed is emitted.

As described above, according to the light-emitting device of one mode of the present invention, the provision of the excitation light distribution control unit can inhibit color irregularity of illumination light. For this reason, an effect is achieved in which color irregularity of illumination light emitted from the light-emitting device can be reduced when a phosphor layer formed of a small-gap phosphor plate is used.

In the light-emitting device according to a second mode of the present invention, in the above first mode, the width of the gap is preferably equal to or longer than 0 nm and equal to or shorter than 40 nm.

According to the above structure, as described above, an effect is achieved in which color irregularity of illumination light emitted from the light-emitting device can be reduced.

In the light-emitting device according to a third mode of the present invention, in the above first or second mode, the excitation light is preferably radiated onto a partial region on an excitation light radiation surface of the phosphor layer.

According to the above structure, since the excitation light is radiated as spot light only onto the partial region on the excitation light radiation surface, an effect is achieved in which a spot property of illumination light can be improved.

In the light-emitting device according to a fourth mode of the present invention, in any one of the above first to third modes, the phosphor is preferably a monocrystalline or polycrystalline garnet-based phosphor.

According to the above structure, an effect is achieved in which thermal conductivity and luminous efficiency of the phosphor layer can be improved.

In the light-emitting device according to a fifth mode of the present invention, in the above fourth mode, the phosphor is preferably the monocrystalline garnet-based phosphor.

According to the above structure, the phosphor layer can be formed of a monocrystalline garnet-based phosphor. Thus, an effect is achieved in which thermal conductivity of the phosphor layer can be further improved compared with the case in which the phosphor layer is formed of a polycrystalline garnet-based phosphor.

In the light-emitting device according to a sixth mode of the present invention, in the above fourth or fifth mode, the garnet-based phosphor is preferably an yttrium aluminum garnet (YAG) phosphor.

According to the above structure, an effect is achieved in which a phosphor layer particularly excellent in luminous efficiency and heat dissipation properties is achieved.

In the light-emitting device according to a seventh mode of the present invention, in any one of the above first to sixth modes, the excitation light distribution control unit preferably controls light distribution of the excitation light by scattering the excitation light.

According to the above structure, an effect is achieved in which the light distribution of the excitation light can be controlled by scattering the excitation light by the excitation light distribution control unit.

In the light-emitting device according to an eighth mode of the present invention, in the above seventh mode, the excitation light distribution control unit may be a sealing layer (1bs) which seals scatterer particles (1bp) for scattering the excitation light.

According to the above structure, an effect is achieved in which the excitation light distribution control unit can be achieved by the sealing layer which seals scatterer particles.

In the light-emitting device according to a ninth mode of the present invention, in the above eighth mode, the sealing layer preferably has a thickness equal to or longer than 10 μm and equal to or shorter than 50 μm.

According to the above structure, since the excitation light distribution control unit can be formed to be sufficiently thin, an effect is achieved in which the spot property of illumination light can be further improved.

In the light-emitting device according to a tenth mode of the present invention, in the above seventh mode, a concavo-convex shape (scattering layer 1bt) may be formed on the excitation light radiation surface of the phosphor layer as the excitation light distribution control unit.

According to the above structure, the excitation light distribution control unit can be formed by forming the concavo-convex shape on the excitation light radiation surface of the phosphor layer. For this reason, an effect is achieved in which the excitation light distribution control unit can be achieved without adding a member different from the phosphor layer.

In the light-emitting device according to an eleventh mode of the present invention, in any one of the above first to tenth modes, the light-emitting device preferably further includes a dichroic mirror (21) which transmits the excitation light and reflects the fluorescence, the dichroic mirror provided to the phosphor layer on an incident side of the excitation light.

According to the above structure, of fluorescence emitted from the phosphor layer, a fluorescence of the phosphor layer headed toward the incident side of the excitation light is reflected by the dichroic mirror and can again be headed toward the phosphor layer. Thus, an effect is achieved in which use efficiency of the fluorescence can be improved.

In the light-emitting device according to a twelfth mode of the present invention, in any one of the above first to eleventh modes, the light-emitting device preferably further includes a light-transmitting substrate (31) which supports the phosphor layer.

According to the above structure, the phosphor layer can be supported by the light-transmitting substrate. Thus, when the phosphor layer is formed to be thin, the phosphor can be prevented from being easily cracked even when a downward external force is applied to the phosphor layer. For this reason, an effect is achieved in which the phosphor layer can be easily handled even when the phosphor layer is formed to be thin.

In the light-emitting device according to a thirteenth mode of the present invention, in any one of the above first to twelfth modes, the light-emitting device may further include a light shielding unit (reflecting unit 41) which covers a part of a surface of the phosphor layer on a fluorescence exit side and shields the excitation light and the fluorescence.

According to the above structure, in accordance with the shape of the light shielding unit which covers a part of the surface of the phosphor layer on the fluorescence exit side, the shape of an opening (a portion not covered with the light shielding unit) on the surface of the phosphor layer on the fluorescence exit side can be defined. For this reason, an effect is achieved in which a pattern of illumination light corresponding to the shape of the opening can be acquired.

In the light-emitting device according to a fourteenth mode of the present invention, in any one of the above first to twelfth modes, the light-emitting device may further include a light shielding unit which covers a part of the excitation light radiation surface of the phosphor layer and shields the excitation light and the fluorescence (reflecting unit 51), and the excitation light distribution control unit may be provided on a portion of the excitation light radiation surface not covered with the light shielding unit.

According to the above structure, in accordance with the shape of the light shielding unit which covers a part of the excitation light radiation surface of the phosphor layer, the shape of an opening (a portion not covered with the light shielding unit) on the excitation light radiation surface of the phosphor layer can be defined. For this reason, an effect is achieved in which a pattern of illumination light corresponding to the shape of the opening can be acquired.

In the light-emitting device according to a fifteenth mode of the present invention, in the above thirteenth or fourteenth mode, according to Claim 11 or 12, the light shielding unit is a reflecting unit (41) which reflects the excitation light and the fluorescence.

According to the above structure, since the light shielding unit can be caused to function as a reflecting unit, an effect is achieved in which use efficiency of the excitation light and the fluorescence can be improved.

In the light-emitting device according to a sixteenth mode of the present invention, in the above thirteenth or fourteenth mode, the light shielding unit may be an optical absorbing unit which absorbs the excitation light and the fluorescence.

According to the above structure, an effect is achieved in which the light shielding unit can be achieved by the light absorbing unit.

In the light-emitting device according to a seventeenth mode of the present invention, in any one of the above first to sixteenth modes, the excitation light source may be a semiconductor laser (10a to 10c) which emits laser light as the excitation light.

Meanwhile, when a semiconductor laser is used as an excitation light source, laser light emitted from the semiconductor laser has relatively high power density per unit area. Thus, when the laser light is emitted from the light-emitting device without being scattered, it is concerned that there is a possibility of damaging safety of the light-emitting device.

However, according to the above structure, by controlling the light distribution of the laser light by the excitation light distribution control unit, the power density of the laser light per unit area can be decreased. For this reason, according to the light-emitting device of one mode of the present invention, an effect is achieved in which safety of the light-emitting device can be enhanced even when a semiconductor laser is used as an excitation light source.

In the light-emitting device according to an eighteenth mode of the present invention, in any one of the above first to seventeenth modes, a surface of the phosphor layer onto which the excitation light is radiated is preferably opposed to a surface of the phosphor layer from which the fluorescence is emitted.

According to the above structure, an effect is achieved in which a transmissive light-emitting device can be achieved as a light-emitting device according to one embodiment of the present invention.

### [Notes]

The present invention is not limited to each of the embodiments described above but can be variously modified in a scope described in the claims. An embodiment acquired by combining technical means disclosed in different embodiments as appropriate is also included in the technical scope of the present invention. Furthermore, by combining technical means disclosed in each of the embodiments, a novel technical feature can be formed.

### [Other Representations of Present Invention]

Note that the present invention can also be represented as follows.

That is, a light-emitting device according to one mode of the present invention includes an excitation light source, a wave conversion member substantially not containing a scattering substance, and an excitation light distribution control unit, and the excitation light distribution control unit is provided to the wave conversion member on a side onto which excitation light is radiated.

Also, in the light-emitting device according to one mode of the present invention, the excitation light via the excitation light distribution control unit is radiated onto a part of the wavelength conversion member.

Also, in the light-emitting device according to one mode of the present invention, the wave conversion member substantially not containing the scattering substance is a single crystal or polycrystal.

Also, in the light-emitting device according to one mode of the present invention, the excitation light distribution control unit is a thin film containing a minute scattering substance.

Also, in the light-emitting device according to one mode of the present invention, the thin film has a thickness equal to or longer than 10 μm and equal to or shorter than 50 μm.

Also, in the light-emitting device according to one mode of the present invention, the excitation light distribution control unit is acquired by performing concavo-convex processing on the wavelength conversion member.

Also, in the light-emitting device according to one mode of the present invention, the excitation light scattering unit includes a dichroic mirror.

Also, in the light-emitting device according to one mode of the present invention, the wavelength conversion member is provided on a substrate.

Also, in the light-emitting device according to one mode of the present invention, a reflecting member including an opening is provided on a light-emitting region side of the wavelength conversion member.

Also, in the light-emitting device according to one mode of the present invention, the excitation light distribution control unit includes an opening, and the excitation light is radiated onto the opening.

### REFERENCE SIGNS LIST

1, 3, 5 light-emitting unit
1a phosphor layer
1b excitation light distribution control unit
1bs sealing layer
1bp scatterer particle
1bt scattering layer (concavo-convex shape)
21 dichroic mirror
31 substrate
41, 51 reflecting unit (light shielding unit)
100, 200, 300, 400, 500 light-emitting device

1. A light-emitting device which emits excitation light as part of illumination light, the light-emitting device comprising:
an excitation light source which emits the excitation light, which is visible light;
a phosphor layer formed of a small-gap phosphor plate which emits a fluorescence upon reception of the excitation light emitted from the excitation light source; and
an excitation light distribution control unit which controls light distribution of the excitation light and guides the excitation light to inside of the phosphor layer, wherein
the small-gap phosphor plate is a phosphor plate in which a gap that is present inside has a width equal to or longer than 0 nm and equal to or shorter than one tenths of a wavelength of the excitation light, and
the excitation light is laser light in a wavelength range equal to or longer than 420 nm and equal to or shorter than 490 nm.

2. The light-emitting device according to claim 1, wherein
the width of the gap is equal to or longer than 0 nm and equal to or shorter than 40 nm.

3. The light-emitting device according to claim 1, wherein
the excitation light is radiated onto a partial region on an excitation light radiation surface of the phosphor layer.

4. The light-emitting device according to claim 1, wherein
the phosphor is a monocrystalline or polycrystalline garnet-based phosphor.

5. The light-emitting device according to claim 4, wherein
the phosphor is the monocrystalline garnet-based phosphor.

6. The light-emitting device according to claim 4, wherein
the garnet-based phosphor is an yttrium aluminum garnet (YAG) phosphor.

7. The light-emitting device according to claim 1, wherein
the excitation light distribution control unit controls light distribution of the excitation light by scattering the excitation light.

8. The light-emitting device according to claim 7, wherein
the excitation light distribution control unit is a sealing layer which seals scatterer particles for scattering the excitation light.

9. The light-emitting device according to claim 8, wherein
the sealing layer has a thickness equal to or longer than 10 μm and equal to or shorter than 50 μm.

10. The light-emitting device according to claim 7, wherein
a concavo-convex shape is formed on the excitation light radiation surface of the phosphor layer as the excitation light distribution control unit.

11. The light-emitting device according to claim 1, further comprising:
a dichroic mirror which transmits the excitation light and reflects the fluorescence, the dichroic mirror provided to the phosphor layer on an incident side of the excitation light.

12. The light-emitting device according to claim 1, further comprising:
a light-transmitting substrate which supports the phosphor layer.

13. The light-emitting device according to claim 1, further comprising:
a light shielding unit which covers a part of a surface of the phosphor layer on a fluorescence exit side and shields the excitation light and the fluorescence.

14. The light-emitting device according to claim 1, further comprising:
a light shielding unit which covers a part of the excitation light radiation surface of the phosphor layer and shields the excitation light and the fluorescence, wherein
the excitation light distribution control unit is provided on a portion of the excitation light radiation surface not covered with the light shielding unit.

15. The light-emitting device according to claim 13, wherein
the light shielding unit is a reflecting unit which reflects the excitation light and the fluorescence.

16. The light-emitting device according to claim 13, wherein
the light shielding unit is an optical absorbing unit which absorbs the excitation light and the fluorescence.

17. (canceled)

18. The light-emitting device according to claim 1, wherein
a surface of the phosphor layer onto which the excitation light is radiated is opposed to a surface of the phosphor layer from which the fluorescence is emitted.
